(19) United States
(12) Patent Application Publication
(10) Pub. No.: US 2011/0036385 A1
(43) Pub. Date: Feb. 17, 2011

(54) THERMOELECTRIC COMPOSITE, AND THERMOELECTRIC DEVICE AND THERMOELECTRIC MODULE INCLUDING THE THERMOELECTRIC COMPOSITE

(75) Inventors: Kyu-hyoung LEE, Yongin-si (KR); Eun-sung LEE, Yongin-si (KR); Sang-mock LEE, Yongin-si (KR); Hyun-sik KIM, Yongin-si (KR)

Correspondence Address: CANTOR COLBURN LLP, 20 Church Street, 22nd Floor, Hartford, CT, 06103, US

(73) Assignee: SAMSUNG ELECTRONICS CO., LTD., Suwon-si (KR)

(21) Appl. No.: 12/853,437

(22) Filed: Aug. 10, 2010

(30) Foreign Application Priority Data
Aug. 17, 2009 (KR) 10-2009-0075729

(51) Int. Cl. H01L 35/12; C09K 5/00

(52) U.S. Cl. 136/236.1; 252/71; 252/78.1; 252/78.3; 252/73; 977/773

(57) ABSTRACT

A thermoelectric composite including a thermoelectric material matrix, a plurality of ceramic nanoparticles, and a bipolar dispersant, wherein the bipolar dispersant bonds the ceramic nanoparticles to the thermoelectric material matrix.

### CROSS-REFERENCE TO RELATED APPLICATIONS

This application claims priority to Korean Patent Application No. 10-2009-0075729, filed on Aug. 17, 2009, and all the benefits accruing therefrom under 35 U.S.C. §119, the content of which in its entirety is herein incorporated by reference.

### BACKGROUND

1. Field

The present disclosure relates to a thermoelectric composite, a thermoelectric device including the thermoelectric composite, and a thermoelectric module including the thermoelectric composite, and more particularly, to a thermoelectric composite having improved thermoelectric properties obtained by improving dispersion of ceramic nanoparticles introduced as a phonon scattering center, a thermoelectric device including the thermoelectric composite, and a thermoelectric module including the thermoelectric composite.

2. Description of the Related Art

In general, thermoelectric materials are materials that are used in active cooling and waste heat power generation based on the Peltier effect and the Seebeck effect. The Peltier effect is a phenomenon in which, as illustrated in FIG. 1, holes of a p-type material and electrons of an n-type material move when a DC voltage is applied, and thus exothermic and endothermic reactions occur at opposite ends of each of the n-type and p-type materials. The Seebeck effect is a phenomenon in which, as illustrated in FIG. 2, holes and electrons move when heat is provided by an external heat source and thus electric current flows in a material, thereby converting a temperature difference into electrical power.

Active cooling using a thermoelectric material improves the thermal stability of a device, does not produce vibration and noise, and does not use a separate condenser and refrigerant and thus is regarded as an environmentally friendly method of cooling. Active cooling using a thermoelectric material can be applied in a refrigerant-free refrigerator, an air conditioner, and various micro-cooling systems. In particular, if a thermoelectric device is attached to memory device, the temperature of the memory device may be maintained at a uniform and stable level while an increase in the entire volume of the memory device and the cooling system is smaller than when a commercially available cooling system is used. Thus, use of a thermoelectric device in a memory device may contribute to higher performance.

In addition, when a thermoelectric material is used for thermoelectric power generation based on the Seebeck effect, waste heat is used as an energy source. Thus, the energy efficiency of a vehicle engine, an exhaust device, a waste incinerator, a steel mill, or a medical device power source which uses heat from a human body, may be increased, or the waste heat can be collected for use in another application.

The performance of the thermoelectric material is evaluated using a dimensionless performance index, which is defined by Equation 1.

$$ZT = \frac{{S}^{2} σ T}{k} \qquad Equation 1$$

wherein S is a Seebeck coefficient, σ is an electrical conductivity, T is an absolute temperature, and κ is a thermal conductivity.

To increase the value of ZT, a material having a low thermal conductivity is desirable.

### SUMMARY

Provided is a thermoelectric composite having high thermoelectric performance obtained by increasing a Seebeck coefficient.

Provided is a thermoelectric device including the thermoelectric composite.

Provided is a thermoelectric module including the thermoelectric device.

Additional aspects will be set forth in part in the description which follows and, in part, will be apparent from the description.

According to an aspect, a thermoelectric composite includes a thermoelectric material matrix, a plurality of ceramic nanoparticles, and a bipolar dispersant, wherein the bipolar dispersant bonds the ceramic nanoparticles to the thermoelectric material matrix.

The bipolar dispersant may have an acidic functional group and a basic functional group.

In an embodiment, the basic functional group of the bipolar dispersant is hypothesized to bond to the thermoelectric material, which has an acidic surface, and the acidic functional group of the bipolar dispersant is understood to bond to the ceramics particles, which have a weakly acidic surface. The bond may be a Coulomb bond formed by electric charge.

The bipolar dispersant may include a mercapto acid, a silane salt, or a combination thereof.

The bipolar dispersant may be a compound represented by Formula 1, a compound represented by Formula 2, or a combination thereof:

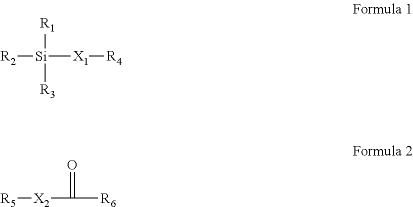

wherein:

R₁, R₂, and R₃ are each independently a hydrogen atom, a halogen atom, a carboxylic group, a thiol group, a substituted or unsubstituted C1-C10 alkoxy group, or a substituted or unsubstituted C1-C10 alkyl group, and at least one of R₁, R₂, and R₃ is a C1-C10 alkoxy group, R₄ is an amino group, a hydroxyl group, or a cyano group, and X₁ is a single bond, a substituted or unsubstituted C1-C20 alkylene group, a substituted or unsubstituted C1-C20 hetero alkylene group, a substituted or unsubstituted C1-C20 alkenylene group, or a substituted or unsubstituted C1-C20 alkynylene group; and

wherein:

R₅ is a thiol group,

R₆ is a hydroxyl group, and

X₂ is a single bond, a substituted or unsubstituted C1-C20 alkylene group, a substituted or unsubstituted C1-C20 hetero alkylene group, a substituted or unsubstituted C1-C20 alkenylene group, or a substituted or unsubstituted C1-C20 alkynylene group.

The bipolar dispersant may be a compound represented by Formula 3, a compound represented by Formula 4, or a combination thereof:

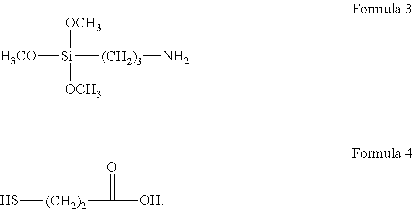

The thermoelectric material matrix may include a Bi—Te alloy.

The thermoelectric material matrix may include a compound represented by Formula 5:

(A₁₋ₐA′ₐ)₂(B_{1-b}B′_{b})₃ Formula 5

wherein A and A′ are different from each other, A is a Group 15 element, and A′ includes a Group 13 element, a Group 14 element, a Group 15 element, a rare-earth element, or a transition metal; B and B′ are different from each other, B is a Group 16 element, and B′ includes a Group 14 element, a Group 15 element, a Group 16 element; 0≦a<1; and 0≦b<1.

The ceramic nanoparticles may comprise an oxide, a nitride, a carbide, or a combination thereof.

The ceramic nanoparticles may be TiO₂ particles.

According to another aspect, a thermoelectric composite includes a thermoelectric material matrix, and a plurality of ceramic nanoparticles, wherein the ceramic nanoparticles are dispersed in the thermoelectric material matrix.

According to another aspect, a thermoelectric device includes the thermoelectric composite described above.

According to another aspect, a thermoelectric device includes: a first insulating substrate on which a first electrode is disposed; a second insulating substrate on which a second electrode is patterned; a p-type thermoelectric device; and an n-type thermoelectric device, wherein the p-type thermoelectric device and the n-type thermoelectric device each contact the first electrode and the second electrode, and wherein the p-type thermoelectric device or the n-type thermoelectric device include the thermoelectric composite described above.

### BRIEF DESCRIPTION OF THE DRAWINGS

These and/or other aspects will become apparent and more readily appreciated from the following description of the embodiments, taken in conjunction with the accompanying drawings in which:

FIG. 1 is a schematic view to explain thermoelectric cooling by the Peltier effect;

FIG. 2 is a schematic view to explain thermoelectric power generation by the Seebeck effect;

FIG. 3 is a schematic view illustrating an exemplary embodiment of bonding of ceramic nanoparticles to a thermoelectric material matrix by a bipolar dispersant;

FIG. 4 is a schematic view illustrating an exemplary embodiment of dispersibility of ceramic nanoparticles before and after a bipolar dispersant is used;

FIG. 5 is an exemplary embodiment of a thermoelectric module;

FIG. 6 is a scanning electron microscopic (“SEM”) image of a thermoelectric composite obtained according to Example 1;

FIG. 7 is a SEM image of a thermoelectric composite obtained according to Comparative Example 2;

FIG. 8 is a SEM image of a thermoelectric composite obtained according to Comparative Example 3;

FIG. 9 is a graph of electrical conductivity (Siemens per centimeter, S/cm) versus temperature (degrees Kelvin, K) of thermoelectric devices using thermoelectric composites obtained according to Examples 1 through 4 and Comparative Example 1;

FIG. 10 is a graph of a Seebeck coefficient (microvolts per Kelvin, μV/K) versus temperature (degrees Kelvin, K) of thermoelectric devices using thermoelectric composites obtained according to Examples 1 through 4 and Comparative Example 1;

FIG. 11 is a graph of a thermal conductivity (watts per meter per Kelvin, W/mK) versus temperature (degrees Kelvin, K) of thermoelectric devices using thermoelectric composites obtained according to Examples 1 through 4 and Comparative Example 1; and

FIG. 12 is a graph of a dimensionless performance index ZT versus temperature (degrees Kelvin, K) of thermoelectric devices using thermoelectric composites obtained according to Examples 1 through 4 and Comparative Example 1.

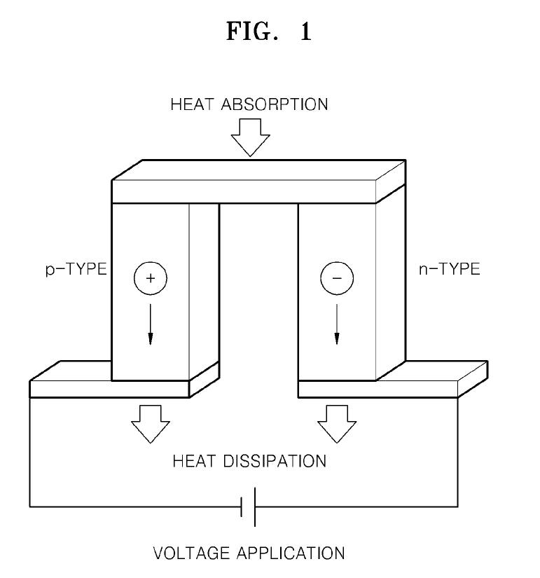

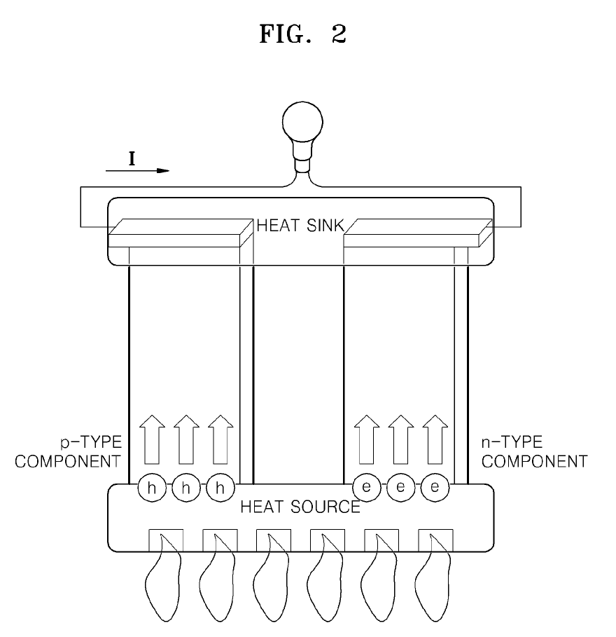

### DETAILED DESCRIPTION

Reference will now be made in detail to embodiments, examples of which are illustrated in the accompanying drawings, wherein like reference numerals refer to the like elements throughout. In this regard, the present embodiments may have different forms and should not be construed as being limited to the descriptions set forth herein. Accordingly, the embodiments are merely described below, by referring to the figures, to explain aspects of the present description.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of the present invention.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below. Unless otherwise defined, all terms (including technical and scientific terms) used herein have the same meaning as commonly understood by one of ordinary skill in the art to which this invention belongs.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

As used herein, unless otherwise provided, the term “substituted” refers to a compound or radical substituted with at least one (e.g., 1, 2, 3, 4, 5, 6 or more) substituents independently selected from a halogen (e.g., F, Cl, Br, I), a carboxyl group, an amino group, a nitro group, a cyano group, a substituted or unsubstituted C1-C20 alkyl group, a substituted or unsubstituted C1-C20 alkenyl group, a substituted or unsubstituted C1-C20 heteroalkyl group, or a substituted or unsubstituted C1-C20 alkoxy group, or a combination thereof, instead of hydrogen, provided that the substituted atom's normal valence is not exceeded.

A thermoelectric composite includes a thermoelectric material matrix 1, a plurality of ceramic nanoparticles 2, and a bipolar dispersant, wherein the bipolar dispersant bonds the thermoelectric material matrix to the ceramic nanoparticles.

In general, a simple and effective method for improving the performance of a thermoelectric material is to introduce a material that functions as a phonon scattering center, wherein the phonons deliver (e.g., transport) heat into a thermoelectric material matrix. For example, a nano-sized ceramic material may be introduced into the thermoelectric material. A ceramic material may reduce a thermal conductivity of the thermoelectric material while maintaining electrical conductivity and the Seebeck coefficient. However, due to non-uniform dispersion and agglomeration of the introduced ceramic material, a decrease in the thermal conductivity is small and thus, the thermoelectric performance is inefficiently improved.

In the disclosed thermoelectric composite, a thermoelectric material is chemically bound to ceramic nanoparticles by a bipolar dispersant so that the ceramic nanoparticles are uniformly dispersed.

Without being bound by theory, it is believed that if a thermoelectric material is an alloy, the thermoelectric material has a thin oxide layer at its surface and thus a particle of the thermoelectric material has a negatively charged (acidic) surface. In addition, the ceramic particles have a positively charged (weakly acidic) surface. Thus, in solution, a basic functional group of the bipolar dispersant becomes positively charged and bonds to the thermoelectric material having the negative surface, and an acidic functional group of the bipolar dispersant becomes negatively charged in solution and bonds to the ceramic particle having the positively charged (weakly acidic) surface. The bond may be a Coulomb bond formed by electric charge. Thus, the thermoelectric material particle may be chemically bonded to the ceramic nanoparticles by the bipolar dispersant. In addition, the foregoing description may similarly applied to an embodiment wherein the thermoelectric material has a basic surface and the ceramic particles have a weakly basic surface.

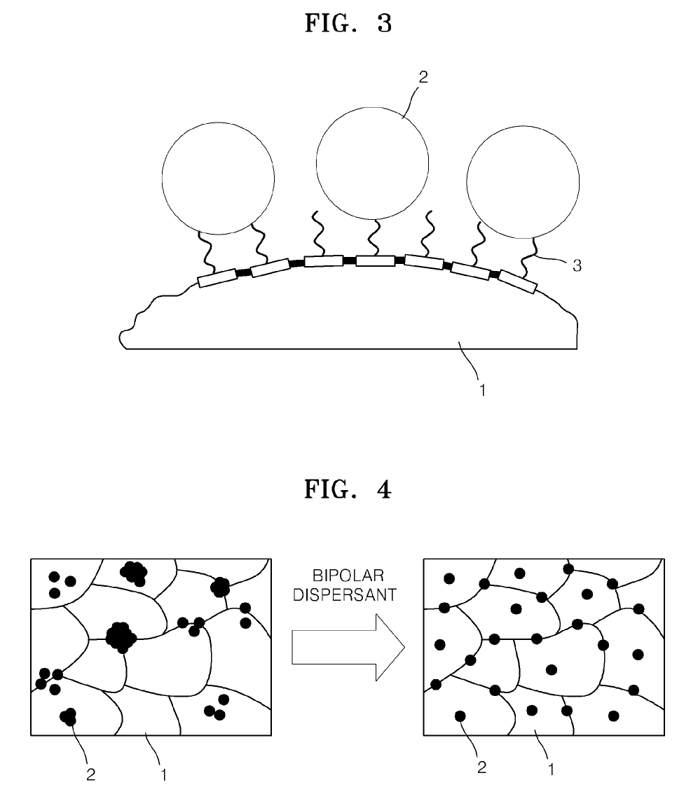

Thus, again without being bound by theory, the bipolar dispersant has an acidic functional group spatially separated from a basic functional group. The acidic functional group and the basic functional group may respectively become negatively charged and positively charged in a solvent such as water, an organic solvent, or a combination thereof. In an embodiment, the electrically charged bipolar dispersant chemically bonds to the thermoelectric material and ceramic nanoparticles which are also electrically charged. For example, the bipolar dispersant may combine with the thermoelectric material and the ceramic nanoparticles by a Coulomb bond. An exemplary embodiment of the chemical bond is illustrated schematically in FIG. 3. Referring to FIG. 3, in an embodiment a basic end of the electrically charged bipolar dispersant 3 bonds to the thermoelectric material matrix 1 and an acidic end bonds to the ceramic nanoparticles 2, and thus the ceramic nanoparticles are more easily dispersed. Due to the increased dispersibility of the ceramic nanoparticles, which functions as a phonon scattering center, the ceramic nanoparticles are less agglomerated. If the bipolar dispersant is not used, the ceramic nanoparticles are insufficiently dispersed and the ceramic nanoparticles agglomerate. However, if the bipolar dispersant is used, the ceramic nanoparticles are sufficiently dispersed. For example, when the bipolar dispersant is used, ceramic nanoparticles having an average particle diameter of equal to or less than about 50 nanometers (“nm”), specifically about 1 nm to about 50 nm, more specifically about 5 nm to about 40 nm, are obtained in the thermoelectric composite. Thus, the thermal conductivity of the thermoelectric material is more effectively reduced.

The bipolar dispersant described above may be any compound having an acidic functional group and a basic functional group spatially separated from each other. In an embodiment, the acidic functional group and the basic functional group are separated by at least one atom, specifically at least two atoms, and more specifically at least three atoms. In another embodiment the acidic functional group and the basic functional group are at opposite ends of the compound, respectively. The bipolar dispersant may be a compound represented by Formula 1, a compound represented by Formula 2, or a combination thereof:

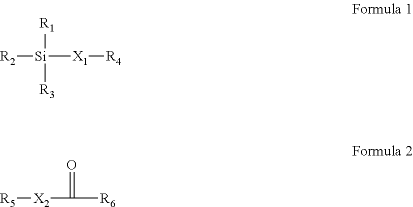

wherein

R₁, R₂, and R₃ are each independently a hydrogen atom, a halogen atom, a carboxylic group, a thiol group, a substituted or unsubstituted C1-C10 alkoxy group, or a substituted or unsubstituted C1-C10 alkyl group, and at least one of R₁, R₂, and R₃ is a C1-C10 alkoxy group,

R₄ is an amino group, a hydroxyl group, or a cyano group, and

X₁ is a single bond, a substituted or unsubstituted C1-C20 alkylene group, a substituted or unsubstituted C1-C20 hetero alkylene group, a substituted or unsubstituted C1-C20 alkenylene group, or a substituted or unsubstituted C1-C20 alkynylene group; and

wherein

R₅ is a thiol group,

R₆ is a hydroxyl group, and

X₂ is a single bond, a substituted or unsubstituted C1-C20 alkylene group, a substituted or unsubstituted C1-C20 heteroalkylene group, a substituted or unsubstituted C1-C20 alkenylene group, or a substituted or unsubstituted C1-C20 alkynylene group.

An example of the bipolar dispersant is a silane salt. The silane salt has an amino group, a hydroxyl group, or a cyano group, each of which is a basic functional group, at one end, and a carboxylic group that is an acidic functional group at the other end, and thus enables a chemical bond between the thermoelectric material matrix and the ceramic nanoparticles. The silane salt may be any material that has an amino group, a hydroxyl group, or a cyano group, each of which is a basic functional group, spatially separated from, e.g., at one end, and a carboxylic group that is an acidic functional group, e.g., at the other end. Examples of the silane salt include 3-aminopropyltriethoxysilane, 3-aminopropyltris(methoxyethoxyethoxy)silane, benzoyloxypropyltrimethoxysilane, 2-cyanoethyltrimethoxysilane, and 3-cyanopropyltriethoxysilane.

An example of the compound represented by Formula 1 is a compound represented by Formula 3, and an example of the compound represented by Formula 2 may be a compound represented by Formula 4:

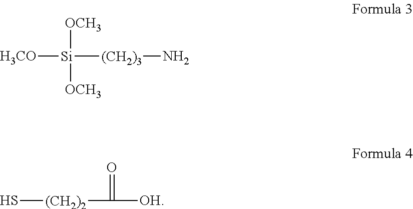

Combinations comprising the compound represented by Formula 3 and the compound represented by Formula 4 can be used.

In the compounds represented by Formulas 3 and 4, the amino group and the hydroxyl group are basic functional groups, and are positively charged in a solvent. Thus, the amino group and the hydroxyl group are combined with the thermoelectric material matrix that has, in general, a negatively charged surface, by a chemical ionic bond, including a bond having substantial ionic character. In the compounds represented by Formulas 3 and 4, the methoxy group and the thiol group are acidic functional groups, and are negatively charged in a solvent. Thus, the methoxy group and the thiol group combine with the ceramic nanoparticles which are, in general, positively charged, by anionic bond, including a bond having substantial ionic character, and thus the ceramic nanoparticles are uniformly dispersed.

As a thermoelectric material that constitutes the thermoelectric material matrix bonding to the ceramic nanoparticles by the bipolar dispersant, a thermoelectric material comprising a Bi—Te alloy may be used without any limitations.

In addition, the thermoelectric material that constitutes the thermoelectric material matrix may be a compound represented by Formula 5:

(A₁₋ₐA′ₐ)₂(B_{1-b}B′_{b})₃ Formula 5

wherein:

A and A′ are different from each other, A is a Group 15 element, and A′ includes a Group 13 element, a Group 14 element, a Group 15 element, a rare-earth element, a transition metal, or a combination thereof, wherein “Group” refers to a group of the Periodic Table of the Elements;

B and B′ are different from each other, B is a Group 16 element, and B′ includes a Group 14 element, a Group 15 element, a Group 16 elements, or a combination thereof;

0≦a<1; and

0≦b<1.

In an embodiment in Formula 5, A is Bi or Sb, and B is Se or Te.

In an embodiment in the compound represented by Formula 5, each of A and A′ may be Bi or Sb, and each of B and B′ may be Se or Te.

The compound represented by Formula 5 may be synthesized using various methods as described below, but the synthesis method of the compound represented by Formula 5 is not limited thereto.

Examples of a polycrystalline synthesis method include:

a method using an ampoule, in which source elements are loaded in a selected ratio into an ampoule made of a quartz or metal tube and then the gas in the ampoule is evacuated, the ampoule sealed, and the ampoule heat-treated;

an arc melting method, in which source elements are loaded in a selected ratio into a chamber and then melted by arc discharge under an inert gas atmosphere; and

a method using a solid state reaction, in which a selected mixture ratio of powder sources are, in one method, sufficiently mixed and then processed to obtain a hard product (e.g., a pellet) and then the obtained hard product is heat-treated, or another method, the mixed powder is heat treated, processed, and then sintered.

Examples of a monocrystalline growth method include:

a metal flux method for crystal growth, in which a selected mixture ratio of source elements and an element that provides a condition under which source elements sufficiently grow into a crystal at high temperature are loaded into a crucible and then heat-treated at high temperature;

a Bridgeman method for crystal growth, in which a selected mixture ratio of source elements are loaded into a crucible, an end of the crucible is heated at high-temperature until the source elements are melted, and then the high temperature region is slowly shifted, thereby locally melting the source elements until the entire source elements are exposed to the high-temperature region;

an optical floating zone method for crystal growth, in which a selected mixture ratio of source elements are formed into a seed rod and a feed rod, light emitted from a lamp is focused on a point on the feed rod so that the source elements are locally melted at high temperature, and then the melting zone is slowly shifted upward; and a vapor transport method for crystal growth, in which a selected mixture ratio of source elements are loaded into a bottom portion of a quartz tube and then the bottom portion of the quartz tube is heated and a top portion of the quartz tube is maintained at low temperature. Thus, when the source elements are evaporated, a solid phase reaction occurs at low temperature.

The compound represented by Formula 5 may also be synthesized using a mechanical alloying method in which source powder and steel balls are loaded into a cemented carbide vessel and then the cemented carbide vessel is rotated, thereby forming an alloy-type thermoelectric material by mechanical impact of the steel balls on the source powder.

The ceramic nanoparticles in the thermoelectric composite may include an oxide, a nitride, and a carbide, or a combination comprising at least one of the foregoing. Examples of the oxide include TiO₂, SiO₂, Al₂O₃, Fe₂O₃, ZnO, CeO₂, and ZrO₂, or a combination comprising at least one of the foregoing. Examples of the nitride include BN, Si₃N₄, GaN, and TiN, or a combination comprising at least one of the foregoing. Examples of the carbide include Be₂C, Al₄C₃, Mg₂C₃, and B₄C, or a combination comprising at least one of the foregoing.

The ceramic nanoparticles may be present in a relatively small amount with respect to the thermoelectric material that constitutes the thermoelectric material matrix in order to reduce the thermal conductivity of the thermoelectric material matrix. The ceramic nanoparticles may be included in an amount of about 0.5 weight percent (“weight %”) to about 2.0 weight %, specifically about 1 weight % based on the weight of the thermoelectric material. If the amount of the ceramic nanoparticles is within this range, the thermal conductivity of the thermoelectric composite may be sufficiently decreased without a decrease in thermoelectric performance.

According to an example of a method of bonding the ceramic nanoparticles to the thermoelectric material by a bipolar dispersant, a thermoelectric material powder, ceramics nanoparticles, and a bipolar dispersant are added to a solvent and then the mixture (e.g., the suspension or solution) is sonicated, thereby chemically bonding the ceramic nanoparticles to the thermoelectric material powder. After the sonication, the solvent may be completely evaporated using, for example, an evaporator while heating. The solvent may be water, an organic solvent, or a combination thereof. Examples of the organic solvent include alcohol, ethyl acetate, and acetone. A combination of solvents can be used.

In an embodiment, a thermoelectric device is obtained by molding the thermoelectric composite obtained as described above into a selected shape, or otherwise formed by, for example, cutting thermoelectric composite obtained as described above into a selected shape.

The thermoelectric device may be a p-type thermoelectric device or an n-type thermoelectric device. The thermoelectric device may be a thermoelectric composite structure having a selected shape, for example, a thermoelectric composite in the form of rectangular parallelepiped.

In an embodiment, the thermoelectric device may be a device that is connected to an electrode and generates a cooling effect when an electric current is applied thereto, or a device for generating power due to a difference in temperature.

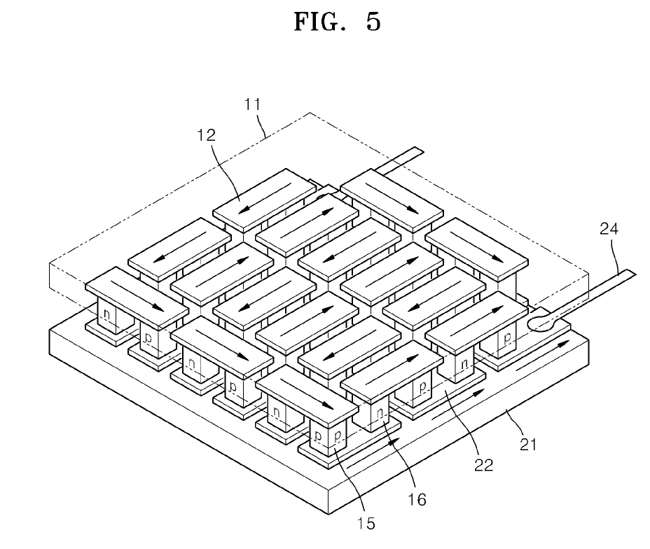

FIG. 5 is diagram of an exemplary embodiment of a thermoelectric module including the thermoelectric device. Referring to FIG. 5, a top electrode 12 and a bottom electrode 22 are patterned on a top insulating substrate 11 and a bottom insulating substrate 21, respectively, and the top electrode 12 and the bottom electrode 22 contact a p-type thermoelectric device 15 and an n-type thermoelectric device 16. The top electrode 12 and the bottom electrode 22 are connected externally by a lead electrode 24.

The top and bottom insulating substrates 11 and 21 may include gallium arsenic (GaAs), sapphire, silicon, firex, quartz, or a combination comprising at least one of the foregoing. The top and bottom electrodes 12 and 22 may include aluminum, nickel, gold, titanium, or a combination comprising at least one of the foregoing, and may have various sizes. The top and bottom electrodes 12 and 22 may be formed with various known patterning methods, such as a lift-off semiconductor process, a deposition method, or a photolithography method.

The thermoelectric module may be, for example, a thermoelectric cooling system or a thermoelectric power generation system. The thermoelectric cooling system may be a micro-cooling system, a generally used cooling device, an air conditioner, or a waste-heat power-generation system, but is not limited thereto. The structure and manufacturing method of the thermoelectric cooling system are well known in the art and thus, will not be described in detail herein.

Embodiments will be described in further detail with reference to the following examples. These examples are for illustrative purposes only and are not intended to limit the scope of the embodiments.

### Example 1

A Bi_{0.5}Sb_{1.5}Te₃ powder, which is a p-type matrix material, was synthesized using an attrition mill for mechanical alloying. In particular, Bi, Sb, and Te, which are source elements, and steel balls having a diameter of 5 millimeters (mm) were loaded into a cemented carbide jar and Ar or N₂ gas was provided thereto to prevent oxidation of the source elements. The weight of the steel balls was 20 times greater than the total weight of all the source elements. An impeller formed of cemented carbide was rotated in the cemented carbide jar at a speed of 500 revolutions per minute (“rpm”), and the oxidation of the source elements caused by heat generated while rotating was prevented by providing cooling water to the outside of the cemented carbide jar.

The Bi_{0.5}Sb_{1.5}Te₃ powder was added to ethyl acetate, and then TiO₂ powder having an average particle diameter of 7 nm was added thereto in an amount of 0.6 weight % of the Bi_{0.5}Sb_{1.5}Te₃ powder. Then, 0.3 g of aminopropyl trimethoxysilane was mixed therewith as a bipolar dispersant.

In order to chemically bond the TiO₂ powder to the Bi_{0.5}Sb_{1.5}Te₃ powder, the mixing was performed using ultrasonic waves for 30 minutes. The resultant product was dried with an evaporator at a temperature of 60° C., thereby completely evaporating ethyl acetate, which is a solvent. Thus, a thermoelectric composite and a dry mixed powder were manufactured.

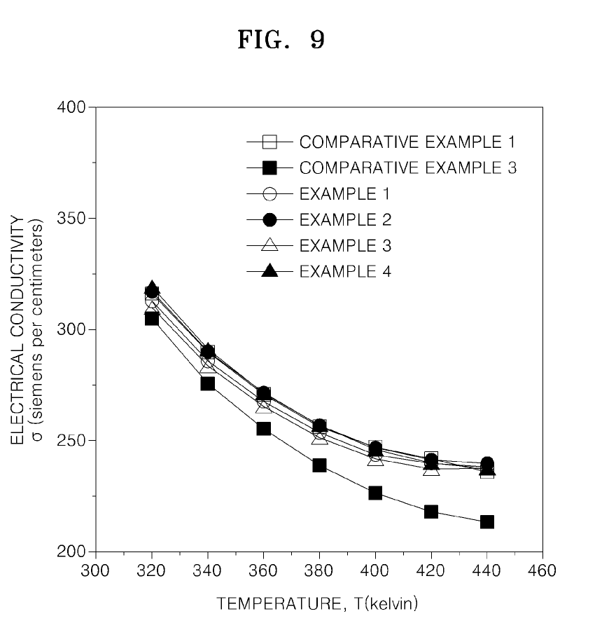

The thermoelectric composite in a dry state was loaded into a mold formed of graphite and hot-pressed under a vacuum (10⁻² torr or less) at a pressure of 70 megapascals (MPa) at a temperature of 400° C., thereby manufacturing a thermoelectric device. The electrical conductivity, Seebeck coefficient, power factor, and thermal conductivity of the thermoelectric device were evaluated, and the results are shown in FIGS. 9 to 12.

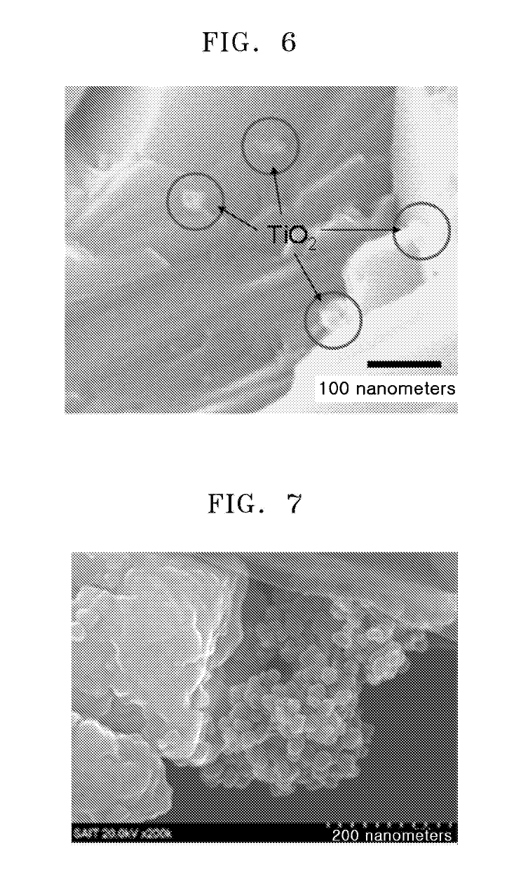

FIG. 6 is a scanning electron microscopic (“SEM”) image of the thermoelectric composite described above. Referring to FIG. 6, it can be seen that TiO₂ nanoparticles, which are ceramic nanoparticles, do not agglomerate and have a particle diameter of 50 nm or less.

### Example 2

A thermoelectric composite was manufactured in the same manner as in Example 1, except that the amount of TiO₂ powder was 1.8 weight % of the Bi_{0.5}Sb_{1.5}Te₃ powder, and thermoelectric characteristics of a thermoelectric device including the thermoelectric composite were evaluated in the same manner as in Example 1, and the results are shown in FIGS. 9 to 12.

### Example 3

A thermoelectric composite was manufactured in the same manner as in Example 1, except that a mercaptopropionic acid was used as the bipolar dispersant, thermoelectric characteristics of a thermoelectric device including the thermoelectric composite were evaluated in the same manner as in Example 1, and the results are shown in FIGS. 9 to 12.

### Example 4

A thermoelectric composite was manufactured in the same manner as in Example 3, except that the amount of TiO₂ powder was 1.8 weight % of the Bi_{0.5}Sb_{1.5}Te₃ powder, thermoelectric characteristics of a thermoelectric device including the thermoelectric composite were evaluated in the same manner as in Example 1, and the results are shown in FIGS. 9 to 12.

### Comparative Example 1

Bi_{0.5}Sb_{1.5}Te₃ powder, which is a p-type matrix material, was synthesized using an attrition mill used for mechanical alloying. In particular, Bi, Sb, and Te, which are source elements, and steel balls having a diameter of 5 mm were loaded into a cemented carbide jar and Ar or N₂ gas was provided thereto to prevent oxidation of the source elements. The weight of the steel balls was 20 times greater than the total weight of all the source elements. An impeller formed of cemented carbide was rotated in the cemented carbide jar at a speed of 500 rpm, and oxidation of the source elements caused by heat generated while rotating was prevented by providing cooling water to the outside of the cemented carbide jar, thereby manufacturing the Bi_{0.5}Sb_{1.5}Te₃ powder.

The Bi_{0.5}Sb_{1.5}Te₃ powder was loaded into a mold formed of graphite and hot-pressed under a vacuum (10⁻² torr or less) at a pressure of 70 MPa at a temperature of 400° C., thereby manufacturing a thermoelectric device. The electrical conductivity, Seebeck coefficient, power factor, and thermal conductivity of the thermoelectric device were evaluated, and the results are shown in FIGS. 9 to 12.

### Comparative Example 2

Bi_{0.5}Sb_{1.5}Te₃ powder, which is a p-type matrix material, was synthesized using an attrition mill used for mechanical alloying. In particular, Bi, Sb, and Te, which are source elements, and steel balls having a diameter of 5 mm were loaded into a cemented carbide jar and Ar or N₂ gas was provided thereto to prevent oxidation of the source elements. The weight of the steel balls was 20 times greater than the total weight of all the source elements. An impeller formed of cemented carbide was rotated in the cemented carbide jar at a speed of 500 rpm, and oxidation of the source elements caused by heat generated while rotating was prevented by providing a cooling water to the outside of the cemented carbide jar, thereby manufacturing the Bi_{0.5}Sb_{1.5}Te₃ powder.

The Bi_{0.5}Sb_{1.5}Te₃ powder was added to ethyl acetate and then TiO₂ powder having an average particle diameter of 7 nm was added thereto in an amount of 0.6 weight % of the Bi_{0.5}Sb_{1.5}Te₃ powder and mixed together using ultrasonic waves for 30 minutes. In order to obtain a dry mixed powder, an evaporator at 60° C. was used to completely evaporate ethyl acetate, which is a solvent, thereby obtaining a thermoelectric composite. FIG. 7 is a SEM image of the thermoelectric composite described above. Referring to FIG. 7, it can be seen that TiO₂ nanoparticles, which are ceramic nanoparticles, agglomerate and thus form secondary particles having an average particle size of 50 nm.

### Comparative Example 3

Bi_{0.5}Sb_{1.5}Te₃ powder, which is a p-type matrix material, was synthesized using an attrition mill used for mechanical alloying. In particular, Bi, Sb, and Te, which are source elements, and steel balls having a diameter of 5 mm were loaded into a cemented carbide jar and Ar or N₂ gas was provided thereto to prevent oxidation of the source elements. The weight of the steel balls was 20 times greater than the total weight of all the source elements. An impeller formed of cemented carbide was rotated in the cemented carbide jar at a speed of 500 rpm, and oxidation of the source elements caused by heat generated while rotating was prevented by providing a cooling water to the outside of the cemented carbide jar.

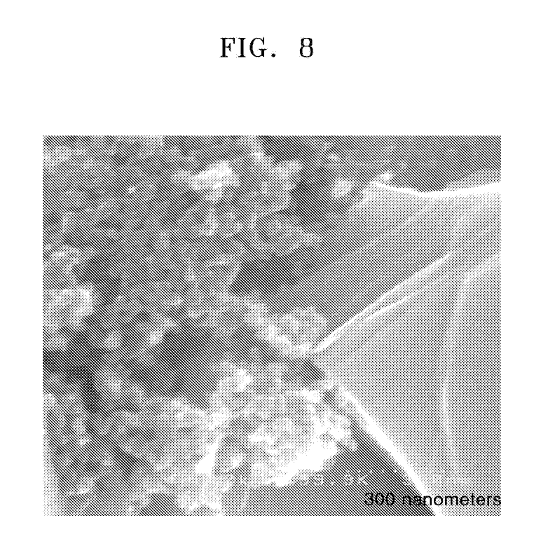

The Bi_{0.5}Sb_{1.5}Te₃ powder was added to ethyl acetate and then TiO₂ powder having an average particle diameter of 7 nm was added thereto in an amount of 1.8 weight % of the Bi_{0.5}Sb_{1.5}Te₃ powder. Then, 0.3 g of a phosphate-based surfactant was mixed therewith as a dispersant. The phosphate-based dispersant is not a bipolar dispersant. Then, the resultant mixture was mixed using ultrasonic waves for 30 minutes. In order to obtain a dry mixed powder, an evaporator at 60° C. was used to completely evaporate ethyl acetate, which is a solvent, thereby obtaining a thermoelectric composite. FIG. 8 is a SEM image of the thermoelectric composite described above. Referring to FIG. 8, it can be seen that TiO₂ nanoparticles, which are ceramic nanoparticles, agglomerate and thus form secondary particles having an average particle size of 50 nm. Thus, the dispersibility improvement effect according to use of the phosphate-based dispersant was negligible.

Thermoelectric Performance Evaluation

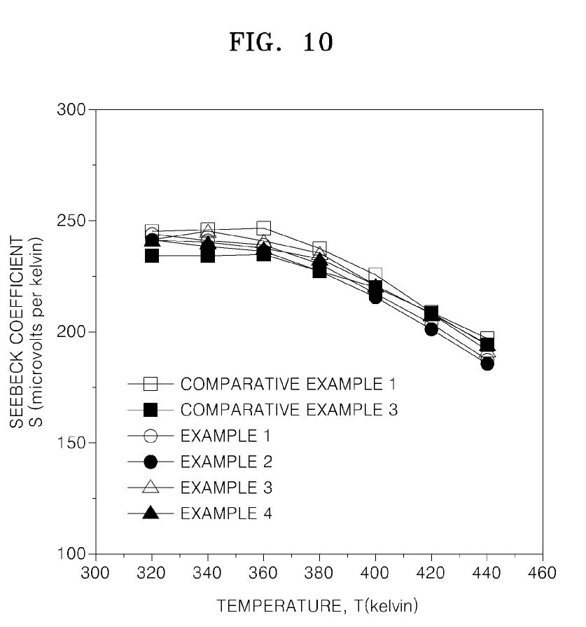

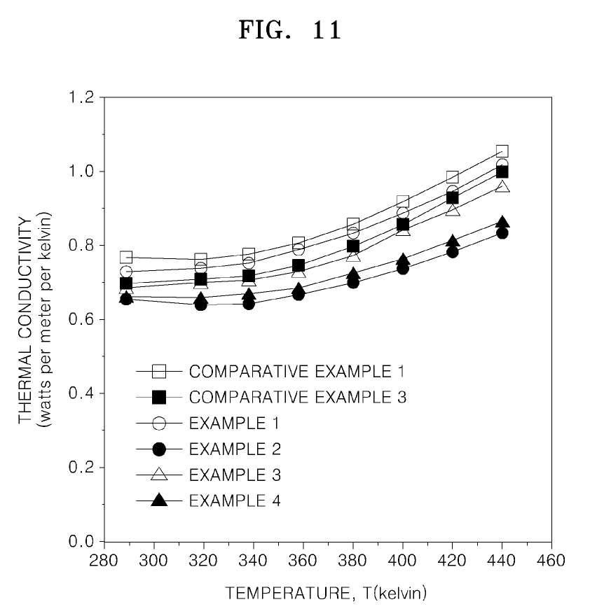

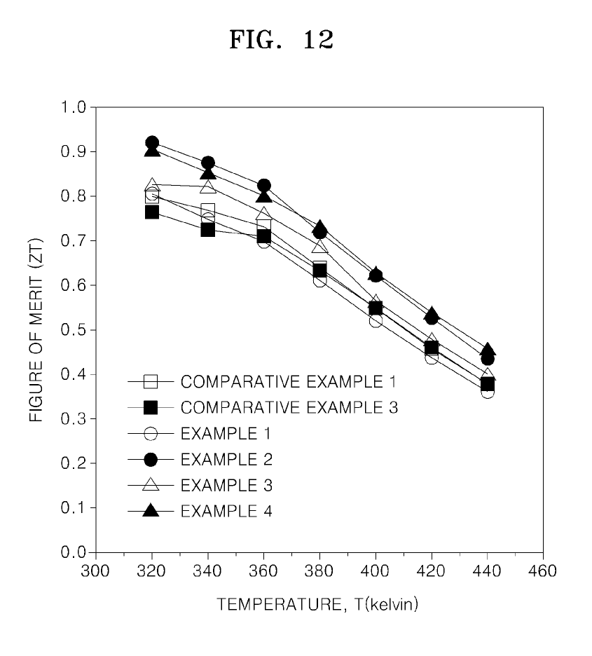

Referring to FIGS. 9 and 10, the electrical conductivity and Seebeck coefficient of the thermoelectric composites including TiO₂ manufactured according to Examples 1 through 4 were similar to those of the p-type Bi_{0.5}Sb_{1.5}Te₃ powder manufactured according to Comparative Example 1. In addition, the electrical conductivity and Seebeck coefficient of the thermoelectric composites including TiO₂ manufactured according to Examples 1 through 4 were greater than those of the composite including Bi_{0.5}Sb_{1.5}Te₃, TiO₂, and a non-bipolar dispersant, which is manufactured according to Comparative Example 3. Referring to FIG. 11, the thermal conductivity of the thermoelectric composites manufactured according to Examples 1 through 4 are reduced by up to about 15% as compared to the Bi_{0.5}Sb_{1.5}Te₃ powder manufactured according to Comparative Example 1, depending on the amount of TiO₂, and by up to about 10% as compared to the composite including Bi_{0.5}Sb_{1.5}Te₃, TiO₂, and a non-bipolar dispersant, which is manufactured according to Comparative Example 3. As a result, as illustrated in FIG. 12, dimensionless performance indices ZT of the thermoelectric composites manufactured according to Examples 1 through 4 are up to 15% greater than those of the Bi_{0.5}Sb_{1.5}Te₃ powder manufactured according to Comparative Example 1 and the composite including Bi_{0.5}Sb_{1.5}Te₃, TiO₂, and a non-bipolar dispersant, which is manufactured according to Comparative Example 3, in the entire temperature region of 320 K through 440 K.

As further described above, a thermoelectric composite according to embodiments described herein has an excellent thermoelectric performance due to low thermal conductivity that is obtained by uniformly dispersing a plurality of ceramic nanoparticles in a thermoelectric composite matrix. A thermoelectric device including the thermoelectric composite and a thermoelectric module including the thermoelectric composite may be used in a refrigerant-free refrigerator, an air conditioner, a waste-heat power-generation system, a thermoelectric nucleic power generator, or a micro-cooling system.

It should be understood that the exemplary embodiments described herein should be considered in a descriptive sense only and not for purposes of limitation. Descriptions of features or aspects within each embodiment should be considered as available for other similar features or aspects in other embodiments.

What is claimed is:

1. A thermoelectric composite comprising:
a thermoelectric material matrix,
a plurality of ceramic nanoparticles, and
a bipolar dispersant,
wherein the bipolar dispersant bonds the ceramic nanoparticles to the thermoelectric material matrix.

2. The thermoelectric composite of claim 1, wherein the bipolar dispersant has an acidic functional group spatially separated from a basic functional group.

3. The thermoelectric composite of claim 1, wherein the bipolar dispersant ionically bonds the ceramic nanoparticles to the thermoelectric material matrix.

4. The thermoelectric composite of claim 1, wherein the bipolar dispersant is a mercapto acid, a silane salt, or a combination thereof.

5. The thermoelectric composite of claim 1, wherein the bipolar dispersant is a compound represented by Formula 1, a compound represented by Formula 2, or a combination thereof: 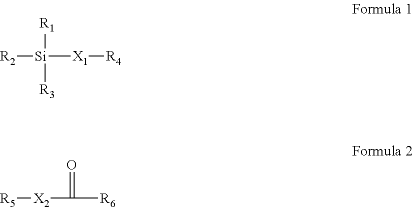
wherein:
R₁, R₂, and R₃ are each independently a hydrogen atom, a halogen atom, a carboxylic group, a thiol group, a substituted or unsubstituted C1-C10 alkoxy group, or a substituted or unsubstituted C1-C10 alkyl group, provided that at least one of R₁, R₂, and R₃ is a C1-C10 alkoxy group,
R₄ is an amino group, a hydroxyl group, or a cyano group, and
X₁ is a single bond, a substituted or unsubstituted C1-C20 alkylene group, a substituted or unsubstituted C1-C20 hetero alkylene group, a substituted or unsubstituted C1-C20 alkenylene group, or a substituted or unsubstituted C1-C20 alkynylene group; and
wherein:
R₅ is a thiol group;
R₆ is a hydroxyl group, and
X₂ is a single bond, a substituted or unsubstituted C1-C20 alkylene group, a substituted or unsubstituted C1-C20 hetero alkylene group, a substituted or unsubstituted C1-C20 alkenylene group, or a substituted or unsubstituted C1-C20 alkynylene group.

6. The thermoelectric composite of claim 1, wherein the bipolar dispersant is a compound represented by Formula 3 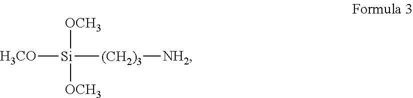
a compound represented by Formula 4 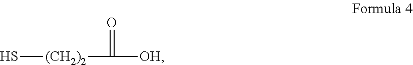
or a combination thereof.

7. The thermoelectric composite of claim 1, wherein the thermoelectric material matrix comprises a thermoelectric material, and wherein the thermoelectric material is a Bi—Te based alloy.

8. The thermoelectric composite of claim 1, wherein the thermoelectric material matrix comprises a thermoelectric material, and wherein the thermoelectric material comprises a compound represented by Formula 5:
(A₁₋ₐA′ₐ)₂(B_{1-b}B′_{b})₃ Formula 5
wherein A and A′ are different from each other, A is a Group 15 element, and A′ comprises a Group 13 element, a Group 14 element, a Group 15 element, a rare-earth element, a transition metal, or a combination thereof;
B and B′ are different from each other, B is a Group 16 element, and B′ comprises a Group 14 element, a Group 15 element, or a Group 16 element, or a combination thereof;
0≦a<1; and
0≦b<1.

9. The thermoelectric composite of claim 1, wherein the ceramic nanoparticles comprise an oxide, a nitride, a carbide, or a combination thereof.

10. The thermoelectric composite of claim 1, wherein the ceramic nanoparticles are TiO₂ nanoparticles.

11. A thermoelectric device comprising the thermoelectric composite of claim 1.

12. A thermoelectric composite comprising:
a thermoelectric material matrix; and
a plurality of ceramic nanoparticles,
wherein the ceramic nanoparticles are dispersed in the thermoelectric material matrix.

13. The thermoelectric composite of claim 12, further comprising a bipolar dispersant, wherein the bipolar dispersant chemically bonds the ceramic nanoparticles to the thermoelectric material matrix.

14. A thermoelectric device comprising the thermoelectric composite of claim 1.

15. The thermoelectric device of claim 14, further comprising:
a first insulating substrate on which a first electrode is disposed;
a second insulating substrate on which a second electrode is disposed;
a p-type thermoelectric device; and
an n-type thermoelectric device,
wherein the p-type thermoelectric device and the n-type thermoelectric device each contact the first electrode and the second electrode, and
wherein the p-type thermoelectric device or the n-type thermoelectric device comprise the thermoelectric composite of claim 1.
